(19) United States
(12) Patent Application Publication
(10) Pub. No.: US 2025/0112615 A1
(43) Pub. Date: Apr. 3, 2025

(54) Elastic Wave Device and Module Using Elastic Wave Device

(71) Applicant: Sanan Japan Technology Corporation, Tokyo (JP)

(72) Inventors: Subei SHUN, Tokyo (JP); Hiroshi NAKAMURA, Tokyo (JP); Shinichi SHIOI, Tokyo (JP)

(21) Appl. No.: 18/900,921

(22) Filed: Sep. 30, 2024

(30) Foreign Application Priority Data
Sep. 30, 2023 (JP) 2023-171008
Sep. 30, 2023 (JP) 2023-171009

(51) Int. Cl. H03H 9/02; H03H 3/08; H03H 9/05; H03H 9/10; H03H 9/145; H03H 9/25

(52) U.S. Cl. CPC H03H 9/02866; H03H 3/08; H03H 9/02637; H03H 9/0552; H03H 9/059; H03H 9/1085; H03H 9/145; H03H 9/25

(57) ABSTRACT

The present application relates to an elastic wave device and a module using the elastic wave device. The elastic wave device comprises a supporting substrate; a dielectric layer formed on the supporting substrate; an insulating layer formed on the dielectric layer; a piezoelectric layer formed on the insulating layer; and a resonator including IDT electrodes formed on the piezoelectric layer. The dielectric layer includes a first strip-shaped acoustic impedance region with a long side direction and a short side direction; and a second strip-shaped acoustic impedance region arranged alternately with the first acoustic impedance region and having a different acoustic impedance from that of the first acoustic impedance region. The elastic wave device of this application provides good temperature characteristics and effectively suppresses spurious response.

### CROSS-REFERENCE TO RELATED APPLICATION

The present disclosure claims priority to Japanese Application No. 2023-171008 and No. 2023-171009, both filed Sep. 30, 2023, the contents of which are herein incorporated by reference in its entirety.

### FIELD

This application relates to an elastic wave device and a module using the elastic wave dvice. In particular, it relates to an elastic surface wave device using SH waves, such as a filter, duplexer, or multiplexer.

### BACKGROUND

In high-frequency communication systems of mobile communication terminals, represented by smartphones, high-frequency filters and other devices are commonly used to remove unnecessary signals from non-communication bands.

In high-frequency filters, elastic wave devices with surface acoustic wave (SAW) elements are typically used. SAW elements are IDT (Interdigital Transducer) elements formed by a pair of comb-shaped electrodes on a piezoelectric layer.

For example, the method of manufacturing an elastic surface wave device is as follows: First, a piezoelectric layer that transmits elastic waves is bonded to a supporting substrate with a smaller coefficient of thermal expansion than the piezoelectric layer to form a multilayer substrate. Then, multiple IDT electrodes are formed on the multilayer substrate using photolithography, and the elastic surface wave device with a predetermined size is obtained by cutting. By using a multilayer substrate, the supporting substrate can suppress dimensional changes in the piezoelectric layer due to temperature changes, thereby stabilizing the frequency characteristics of the elastic wave device.

For example, it is known from Patent Document 1 (Japanese Patent Laid-Open No. 2009-278610) that to improve the temperature characteristics of an elastic wave device, a supporting substrate such as a sapphire substrate with a high Young's modulus and low coefficient of linear expansion is bonded to the piezoelectric layer to suppress expansion and contraction caused by temperature changes.

As described in Patent Document 1, to improve the temperature characteristics of an elastic wave device, a supporting substrate such as a sapphire substrate with a high Young's modulus and low coefficient of linear expansion is bonded to the piezoelectric layer to suppress expansion and contraction caused by temperature changes. However, resonators using such a supporting substrate are prone to spurious response at the high-frequency end, resulting in poor filtering characteristics.

### SUMMARY

This application aims to solve the above problems. Its objective is to provide an elastic wave device with good temperature characteristics and effectively suppress spurious response, as well as a module using the elastic wave device.

In one aspect, this application provides an elastic wave device, comprising:
a supporting substrate;
a dielectric layer formed on the supporting substrate;
an insulating layer formed on the dielectric layer;
a piezoelectric layer formed on the insulating layer;
a resonator including IDT electrodes formed on the piezoelectric layer; wherein the dielectric layer includes a first strip-shaped acoustic impedance region with a long side direction and a short side direction; and a second strip-shaped acoustic impedance region arranged alternately with the first acoustic impedance region and having a different acoustic impedance from that of the first acoustic impedance region; wherein, when the wavelength of the elastic wave determined by the electrode spacing of the IDT electrode is λ, the total thickness of the insulating layer and the piezoelectric layer is 1.0λ or less.

In some embodiments, when the wave length of the elastic wave determined by the electrode spacing of the IDT electrode is λ, the total thickness of the dielectric layer, the insulating layer, and the piezoelectric layer is 1.0λ or less.

This application can provide an elastic wave device with good temperature characteristics and effectively suppress spurious response, as well as a module using the elastic wave device.

The details of one or more embodiments of the present application are set forth in the accompanying drawings and the description below. Other features, objects, and advantages of the present application will be apparent from the description and drawings, and from the claims.

### BRIEF DESCRIPTION OF THE DRAWINGS

The accompanying drawings are intended to provide a further understanding of the present application, constitute part of this application, and illustrate exemplary embodiments of this application. The description and drawings do not limit the scope of the application.

FIG. 1 is a cross-sectional view of the elastic wave device according to the first embodiment of this application.

FIG. 2 is a cross-sectional view of the device chip of the elastic wave device according to the first embodiment of this application.

FIG. 3 is a top view of the functional element of the elastic wave device according to the first embodiment of this application.

FIG. 4 is a graph of the resonance characteristics of the resonator of the elastic wave device according to the first embodiment of this application.

FIG. 5 is a graph comparing the resonance characteristics of the resonator of the elastic wave device according to the first embodiment of this application and a first comparative example.

FIG. 6 is a graph of the resonance characteristics of the resonator of the elastic wave device according to the second embodiment of this application.

FIG. 7 is a graph comparing the resonance characteristics of the resonator of the elastic wave device according to the second embodiment of this application and a second comparative example.

FIG. 8 is a cross-sectional view of the elastic wave device with 5 second acoustic impedance regions 12B arranged within the range of 8 electrode fingers 51b according to the third embodiment of this application.

FIG. 9 is a top view of the functional element of the elastic wave device according to the third embodiment of this application.

FIG. 10 is a diagram illustrating the manufacturing method of the elastic wave device.

FIG. 11 is a longitudinal sectional view of a module suitable for the elastic wave device according to the first, second, or third embodiment of this application.

In the drawings: 1. Elastic wave device; 3. Wiring substrate; 5. Device chip; 7. Packaging portion; 10. Insulating layer; 11. Piezoelectric layer; 12. Dielectric layer; 13. Supporting substrate; 50. Elastic wave element; 12A. First acoustic impedance region; 12B. Second acoustic impedance region; 100. Module; 111. Inductor; 117. Packaging portion; 130. Wiring substrate.

### DETAILED DESCRIPTION

For a better understanding of the objectives, technical solutions, and advantages of the present application, the following description and accompanying drawings provide further details.

Unless otherwise defined, technical or scientific terms used herein should have the same meanings as understood by those skilled in the art to which this application belongs. In this application, terms such as “a,” “an,” “one,” “the,” “these,” and similar expressions are not intended to limit the quantity; they can refer to either the singular or plural. Terms such as “comprising,” “including,” “having,” and their variations are intended to cover non-exclusive inclusions. For example, a process, method, or system, product, or device that includes a list of steps or modules is not limited to only those listed steps or modules but may include other steps or modules not listed or inherent in those processes, methods, systems, products, or devices. In this application, terms such as “connected,” “coupled,” and similar expressions are not limited to physical or mechanical connections but may include electrical connections, whether direct or indirect. The term “plurality” refers to two or more. “And/or” describes the relationship of associated objects, indicating that there are three possible relationships, such as “A and/or B” may indicate: the presence of A alone, the presence of both A and B, or the presence of B alone. Generally, the character “/” indicates an “or” relationship between the associated objects. Terms such as “first,” “second,” “third,” etc., are used for distinguishing similar objects and do not indicate specific orders.

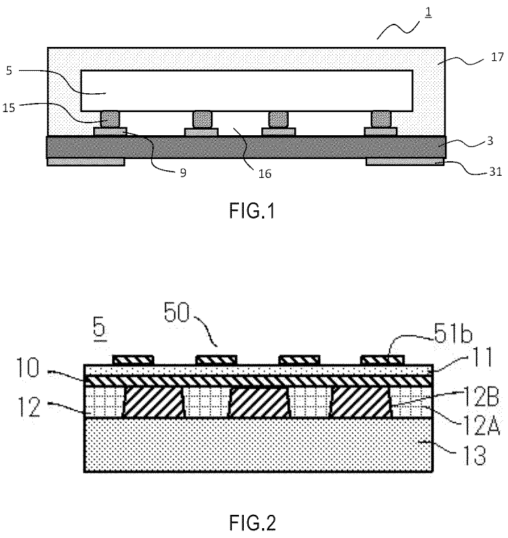

The following describes exemplary embodiments of this application with reference to FIGS. 1 to 11.

### First Embodiment

FIG. 1 is a cross-sectional view of the elastic wave device according to the first embodiment of this application.

As shown in FIG. 1, the elastic wave device 1 includes a wiring substrate 3, external connection terminals 31, a device chip 5, electrode pads 9, bumps 15, and a packaging portion 17.

For example, the wiring substrate 3 is a multilayer substrate made of resin. For instance, the wiring substrate 3 may be a low-temperature co-fired ceramics (LTCC) multilayer substrate composed of multiple dielectric layers.

External connection terminals 31 are formed on the lower surface of the wiring substrate 3. Electrode pads 9 are formed on the main surface of the wiring substrate 3. For example, the electrode pads 9 are made of copper or a copper alloy. The thickness of the electrode pads 9 is about 10 μm to 20 μm.

Bumps 15 are formed on each surface of the electrode pads 9. For example, the bumps 15 are gold bumps with a height of about 10 μm to 50 μm.

A gap 16 is formed between the wiring substrate 3 and the device chip 5.

The device chip 5 is mounted on the wiring substrate 3 using flip-chip bonding via the bumps 15. The device chip 5 is electrically connected to the multiple electrode pads 9 through multiple bumps 15.

The device chip 5 is a substrate on which elastic wave elements 50 are formed. For example, multiple elastic wave elements 50, including filters for transmission and reception, are mainly formed on the main surface of the device chip 5.

The transmission filter is designed to allow the passage of a desired frequency band signal. For example, the transmission filter is formed of multiple series resonators and multiple parallel resonators, constituting a ladder-type filter.

The reception filter is designed to allow the passage of a desired frequency band signal. For example, the reception filter is a ladder-type filter.

The packaging portion 17 is formed to cover the device chip 5. For example, the packaging portion 17 is made of an insulating material such as synthetic resin. In other embodiments, the packaging portion 17 may also be made of metal.

If the packaging portion 17 is made of synthetic resin, the material of the synthetic resin includes epoxy resin, polyimide, etc. Preferably, the packaging portion 17 is formed of epoxy resin and molded using a low-temperature curing process.

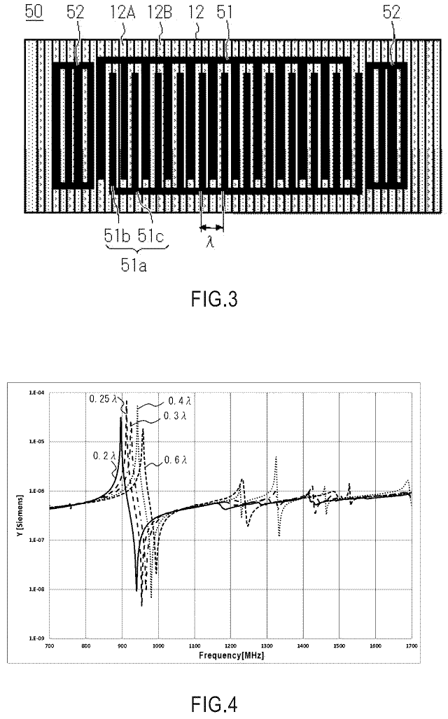

FIG. 2 is a cross-sectional view of the device chip of the elastic wave device according to the first embodiment of this application.

As shown in FIG. 2, the device chip 5 includes an insulating layer 10, a piezoelectric layer 11, a dielectric layer 12, and a supporting substrate 13. The elastic wave element 50 is formed on the piezoelectric layer 11.

The insulating layer 10 is made of silicon dioxide, and when the wavelength of the elastic wave determined by the electrode spacing of the IDT electrode is λ, the thickness of the insulating layer 10 is 0.1λ to 0.9λ. It should be noted that in other embodiments, the insulating layer 10 may also be made of silicon nitride.

The piezoelectric layer 11 may be made of a single-crystal material such as lithium tantalate, lithium niobate, or quartz. It should be noted that in other embodiments, the piezoelectric layer 11 may also be made of piezoelectric ceramics.

When the wavelength of the elastic wave determined by the electrode spacing of the IDT electrode is λ, the thickness of the piezoelectric layer 11 may be 0.1λ to 0.9λ, preferably 0.1λ to 0.3λ.

The total thickness of the insulating layer 10 and the piezoelectric layer 11 is 1.0λ or less.

A semiconductor layer may also be included between the insulating layer 10 and the piezoelectric layer 11. The semiconductor layer may be made of silicon. By using silicon with a thickness of 5 nm to 20 nm in the bonding between the insulating layer 10 and the piezoelectric layer 11, bonding can be achieved without increasing spurious response, thereby improving the bonding effect between the insulating layer 10 and the piezoelectric layer 11.

The dielectric layer 12 includes a first acoustic impedance region 12A and a second acoustic impedance region 12B. The first acoustic impedance region 12A is made of a material such as silicon nitride, silicon oxynitride, silicon, alumina, silicon dioxide, or silicon carbide. The second acoustic impedance region 12B is made of a material such as alumina, aluminum nitride, silicon nitride, silicon oxynitride, silicon, or silicon carbide, and the material used in the first acoustic impedance region 12A is different from that used in the second acoustic impedance region 12B.

When the wavelength of the elastic wave determined by the electrode spacing of the IDT electrode is λ, the thickness of the dielectric layer 12 may be 0.05λ to 0.45λ. The total thickness of the insulating layer 10, the piezoelectric layer 11, and the dielectric layer 12, for example, when the wavelength of the elastic wave determined by the electrode spacing of the IDT electrode is λ, may not exceed 1.0λ.

In the example shown in FIG. 2, the first acoustic impedance region 12A and the second acoustic impedance region 12B are arranged in 3 cycles relative to 4 electrode fingers 51b on the piezoelectric layer 11. That is, within the range of 4 electrode fingers 51b, 3 second acoustic impedance regions 12B are arranged. Further explanation is that the first acoustic impedance region 12A and the second acoustic impedance region 12B are arranged with a spacing different from the spacing of the electrode fingers 51b; the first acoustic impedance region 12A and the second acoustic impedance region 12B are arranged alternately with the same thickness.

The supporting substrate 13 may be made of materials such as sapphire, silicon, alumina, spinel, silicon nitride, aluminum nitride, silicon carbide, silicon oxynitride, diamond, crystal, glass, etc. The smaller the thermal expansion coefficient of the supporting substrate 13, and the higher the Young's modulus, the better the improvement effect on the temperature characteristics of the elastic wave device 1. A typical substrate that meets these conditions is a sapphire substrate. Due to its high hardness and good chemical stability, it is difficult to process the surface into a convex-concave shape or serrated shape, leading to a decrease in yield. Therefore, the supporting substrate 13 is preferably a flat rectangular parallelepiped.

The thickness of the supporting substrate 13 ranges from 50 μm to 200 μm.

FIG. 3 is a top view of the functional element of the elastic wave device according to the first embodiment of this application. The elastic wave element 50 formed on the piezoelectric layer 11 will be described with reference to FIG. 3.

To facilitate explanation, FIG. 3 perspectively shows the piezoelectric layer 11, which is not shown in the figure. For a schematic diagram of its structure, please refer to FIG. 2. An elastic wave element including IDT (Interdigital Transducer) electrodes 51 and a pair of reflectors 52 is formed on the main surface of the piezoelectric layer 11. The IDT electrodes 51 and the pair of reflectors 52 are used to excite elastic waves (mainly SH waves).

Specifically, the IDT electrodes 51 and the pair of reflectors 52 are made of an alloy of aluminum and copper. It should be noted that in other embodiments, the IDT electrodes 51 and the pair of reflectors 52 may also include aluminum, molybdenum, iridium, tungsten, cobalt, nickel, ruthenium, chromium, strontium, titanium, palladium, silver, or suitable metals or alloys of these metals.

Specifically, the IDT electrodes 51 and the pair of reflectors 52 can be formed by stacking multiple metal films, with these metal films stacked to form a laminated metal film. The thickness of the IDT electrodes 51 and the pair of reflectors 52 ranges from 150 nm to 450 nm.

The IDT electrodes 51 include a pair of comb-shaped electrodes 51a. These comb-shaped electrodes 51a are arranged oppositely. The comb-shaped electrodes 51a include multiple electrode fingers 51b and a bus 51c.

Multiple electrode fingers 51b are arranged along the long side direction. The bus 51c connects multiple electrode fingers 51b.

One of the pair of reflectors 52 is adjacent to one side of the IDT electrodes 51, and the other is adjacent to the other side of the IDT electrodes 51.

A dielectric layer 12 is formed between the piezoelectric layer 11 and the supporting substrate 13 (not shown in FIG. 3). As shown in FIG. 3, the first acoustic impedance region 12A and the second acoustic impedance region 12B are respectively formed as striped regions arranged in the long side direction and the short side direction. As shown in FIG. 3, the first acoustic impedance region 12A and the second acoustic impedance region 12B are alternately arranged in the short side direction.

As shown in FIG. 3, the long side directions of the first acoustic impedance region 12A and the second acoustic impedance region 12B are the same as the long side direction of the electrode fingers 51b.

FIG. 4 is a graph of the resonance characteristics of the resonator of the elastic wave device 1 according to the first embodiment of this application. The insulating layer 10 is made of silicon dioxide. The piezoelectric layer 11 is made of single-crystal lithium tantalate. The velocity of the bulk wave propagating in the insulating layer 10 is less than the velocity of the bulk wave propagating in the piezoelectric layer 11. The total thickness of the insulating layer 10 and the piezoelectric layer 11 is set to 0.65λ. That is, when the thickness of the piezoelectric layer 11 is 0.2λ, 0.25λ, 0.3λ, 0.4λ, and 0.6λ, the thickness of the insulating layer 10 is respectively 0.45λ, 0.4λ, 0.35λ, 0.25λ, and 0.05λ, and calculations were performed. The resonance characteristic calculation results of the piezoelectric layer 11 at thicknesses of 0.2λ, 0.25λ, 0.3λ, 0.4λ, and 0.6λ are shown in FIG. 4.

The thickness of the IDT electrodes 51 is set to 0.1λ and is made of aluminum material. The thickness of the dielectric layer 12 is set to 0.25λ. Additionally, the short side direction widths of the first acoustic impedance region 12A and the second acoustic impedance region 12B are the same, with a duty cycle of 50%. The first acoustic impedance region 12A is made of silicon dioxide. The second acoustic impedance region 12B is made of alumina. The supporting substrate 13 is made of a sapphire substrate.

As shown in FIG. 4, the peaks and valleys around 900 MHz to 1000 MHz are due to inherent resonance modes. The peaks and valleys outside this frequency range, specifically around 1200 MHz to 1700 MHz, are due to non-inherent resonance modes, referred to as spurious response. If there are strong spurious response, the characteristics will significantly deteriorate when combining resonators to form filters or other devices. Therefore, the lower the height of the spurious peaks and the depth of the valleys, the better the electrical performance of the elastic wave device 1.

As shown in FIG. 4, the resonance characteristics of the resonator of the elastic wave device according to the first embodiment, at piezoelectric layer 11 thicknesses of 0.2λ, 0.25λ, 0.3λ, 0.4λ, and 0.6λ, show particularly low parasitic responses at thicknesses of 0.2λ, 0.25λ, and 0.3λ. Additionally, when the thickness of the insulating layer 10 is greater than the thickness of the piezoelectric layer 11, the parasitic response is particularly low.

FIG. 5 is a graph comparing the resonance characteristics of the resonator of the elastic wave device 1 according to the first embodiment of this application and a first comparative example. The insulating layer 10 is made of silicon dioxide. The piezoelectric layer 11 is made of lithium tantalate. To make the total thickness of the insulating layer 10 and the piezoelectric layer 11 equal to 0.65λ, when the thickness of the piezoelectric layer 11 is 0.2λ and 0.3λ, the thickness of the insulating layer 10 is respectively set to 0.45λ and 0.35λ, and calculations were performed. Other conditions are the same as those described in FIG. 4.

In the first comparative example, the total thickness of the insulating layer 10 and the piezoelectric layer 11 is set to 0.9λ, that is, when the thickness of the piezoelectric layer 11 is 0.2λ and 0.3λ, the thickness of the insulating layer 10 is respectively set to 0.7λ and 0.6λ, and calculations were performed. The first comparative example does not include a dielectric layer 12. That is, in the first comparative example, both the first acoustic impedance region 12A and the second acoustic impedance region 12B are made of silicon dioxide, and other conditions are the same as those in the first embodiment.

As shown in FIG. 5, under the resonance characteristics of the resonator of the elastic wave device in the first embodiment, with piezoelectric layer 11 thicknesses of 0.2λ and 0.3λ, the total thickness of the insulating layer 10 and the piezoelectric layer 11 significantly improves spurious response compared to the resonance characteristics 0.2λNS and 0.3λNS of the first comparative example at piezoelectric layer 11 thicknesses of 0.2λ and 0.3λ, respectively.

According to the first embodiment described above, an elastic wave device with good temperature characteristics and significantly reduced spurious response can be provided.

### Second Embodiment

In this embodiment, the insulating layer 10 is made of silicon nitride; when the wavelength of the elastic wave determined by the electrode spacing of the IDT electrode is λ, the total thickness of the insulating layer 10 and the piezoelectric layer 11 is preferably 0.7λ or less.

Other structures of this embodiment are the same as in the first embodiment, and therefore, the description is omitted.

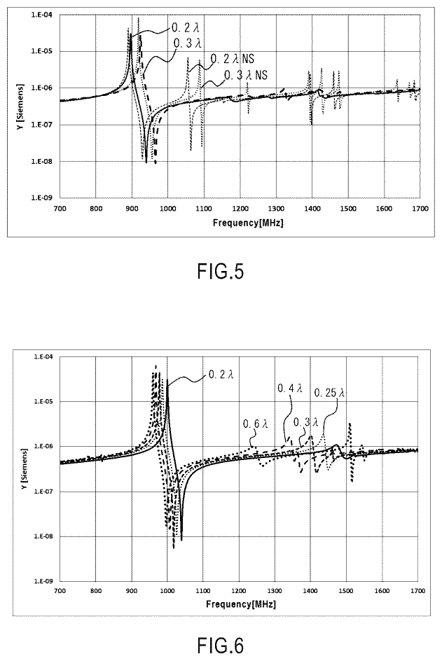

FIG. 6 is a schematic diagram showing the resonance characteristics of the resonator of the elastic wave device 1 according to the second embodiment. The piezoelectric layer 11 is made of single-crystal lithium tantalate. By setting the total thickness of the piezoelectric layer 11 and the insulating layer 10, which is made of silicon nitride, to 0.65λ—where the thickness of the piezoelectric layer 11 is 0.2λ, 0.25λ, 0.3λ, 0.4λ, and 0.6λ, and the thickness of the insulating layer is set to 0.45λ, 0.4λ, 0.35λ, 0.25λ, and 0.05λ, respectively—the calculation results are shown in FIG. 4. The resonance characteristics of the piezoelectric layer 11 at thicknesses of 0.2λ, 0.25λ, 0.3λ, 0.4λ, and 0.6λ are shown in FIG. 4.

The thickness of the IDT electrodes 51 is set to 0.1λ and is made of aluminum. The thickness of the dielectric layer 12 is set to 0.25λ. Additionally, the short side direction widths of the first acoustic impedance region 12A and the second acoustic impedance region 12B are the same, with a duty cycle of 50%. The first acoustic impedance region 12A is made of silicon dioxide. The second acoustic impedance region 12B is made of alumina. The supporting substrate 13 is made of a sapphire substrate.

As shown in FIG. 6, the peaks and valleys around 950 MHz to 1050 MHz are caused by the fundamental resonance mode. The peaks and valleys in the high-frequency range, specifically around 1200 MHz to 1700 MHz, are due to non-fundamental resonance modes, referred to as spurious response. If strong spurious response are present, the characteristics will significantly deteriorate when combining resonators to form filters or other devices. Therefore, the lower the height of the spurious peaks and the depth of the valleys, the better the characteristics.

As shown in FIG. 6, the resonance characteristics of the resonator of the elastic wave device according to the second embodiment, at piezoelectric layer 11 thicknesses of 0.2λ, 0.25λ, 0.3λ, 0.4λ, and 0.6λ, show particularly low parasitic responses at thicknesses of 0.2λ, 0.25λ, and 0.3λ. Additionally, when the thickness of the insulating layer 10 is greater than the thickness of the piezoelectric layer 11, the parasitic response is particularly low.

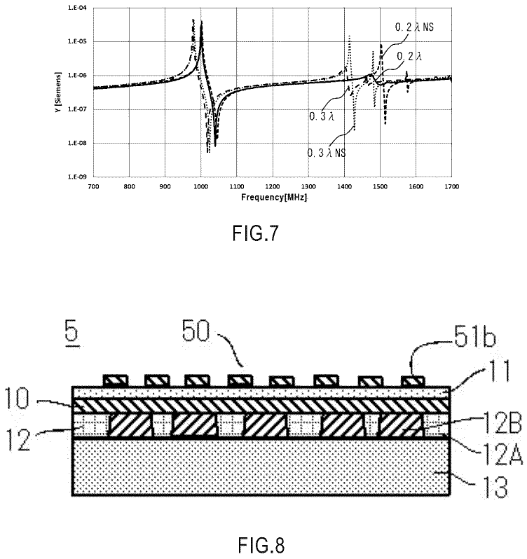

FIG. 7 is a schematic diagram showing the resonance characteristics of the resonator of the elastic wave device 1 according to the second embodiment compared to the second comparative example. The resonator of the elastic wave device 1 in the second embodiment uses a lithium tantalate piezoelectric layer 11. By setting the total thickness of the insulating layer and the piezoelectric layer 11 to 0.65λ—where the thickness of the piezoelectric layer 11 is 0.2λ and 0.3λ, and the thickness of the insulating layer is set to 0.45λ and 0.35λ, respectively—the calculation results are shown in FIG. 7. Other conditions are the same as those described in FIG. 6.

In the second comparative example, the total thickness of the insulating layer and the piezoelectric layer 11 formed on a sapphire substrate is set to 0.9λ—where the thickness of the piezoelectric layer 11 is 0.2λ and 0.3λ, and the thickness of the insulating layer is set to 0.7λ and 0.6λ, respectively—the calculation results are shown in FIG. 7. The second comparative example does not include a dielectric layer 12. That is, in the second comparative example, both the first acoustic impedance region 12A and the second acoustic impedance region 12B are made of silicon dioxide, and other conditions are the same as in the second embodiment.

As shown in FIG. 7, under the resonance characteristics of the resonator of the elastic wave device in the second embodiment, with piezoelectric layer 11 thicknesses of 0.2λ and 0.3λ, the total thickness of the insulating layer and the piezoelectric layer 11 significantly improves spurious response compared to the resonance characteristics 0.2λNS and 0.3λNS of the second comparative example at piezoelectric layer 11 thicknesses of 0.2λ and 0.3λ, respectively.

According to the second embodiment described above, an elastic wave device with good temperature characteristics and significantly reduced spurious response can be provided.

The first and second embodiments described above show good spurious response suppression effects when the first acoustic impedance region 12A and the second acoustic impedance region 12B are arranged in 3 cycles relative to 4 electrode fingers. However, the relationship between the number of cycles of the first acoustic impedance region 12A and the second acoustic impedance region 12B and the number of electrode fingers is not limited to this. However, it is preferable that the number of electrode fingers does not coincide with the number of cycles of the first acoustic impedance region 12A and the second acoustic impedance region 12B. The reason is that when the number of electrode fingers coincides with the number of cycles, the suppression effect of the spurious response will be weakened. For example, as shown in FIG. 8, setting the second acoustic impedance region 12B to 5 cycles within the range of 8 electrode fingers 51b is also feasible. In other words, under the premise where the number of electrode fingers and the number of cycles in the first acoustic impedance region 12A and the second acoustic impedance region 12B are inconsistent, there is no limitation on the combination of the number of electrode fingers and the number of cycles.

### Third Embodiment

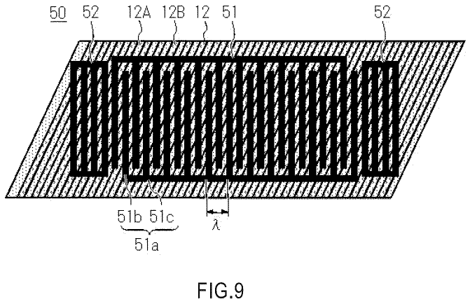

FIG. 9 shows a top view of the functional element 50 of the elastic wave device 1 according to the third embodiment. As shown in FIG. 9, the long side direction of the first acoustic impedance region 12A and the second acoustic impedance region 12B is different from the long side direction of the electrode fingers 51b. By this arrangement, an acoustic impedance difference can be generated in the transverse mode waves, thereby reducing transverse mode spurious response.

Other structures are the same as in the first embodiment, and therefore, the description is omitted.

According to the third embodiment described above, an elastic wave device with significantly reduced high-frequency spurious response and transverse mode spurious response can be provided.

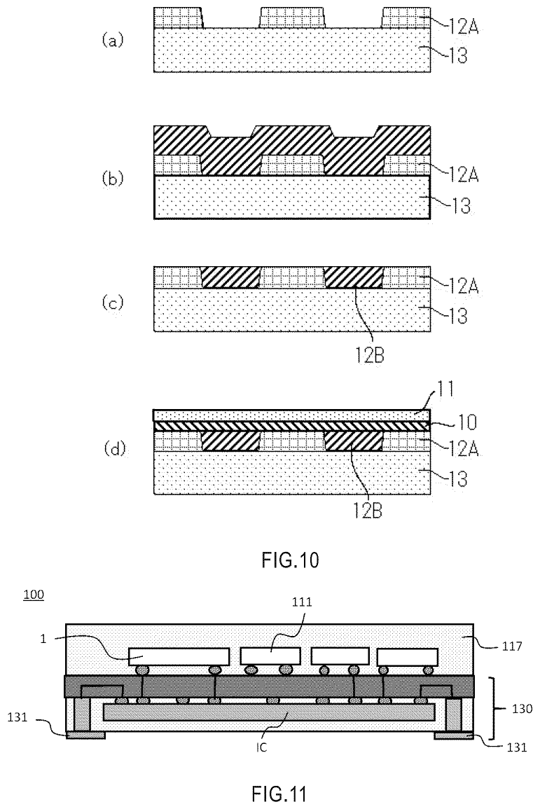

Next, the manufacturing method of the elastic wave device 1 according to the first and second embodiments is described. FIG. 10 is a diagram illustrating the manufacturing method of the elastic wave device 1 according to the first and second embodiments.

As shown in FIG. 10(a), a first acoustic impedance film is formed on the supporting substrate 13. Then, the first acoustic impedance film is patterned. The patterning process is selected according to the material of the first acoustic impedance film, such as lift-off or etching.

As shown in FIG. 10(b), the area from which the first acoustic impedance film is removed through the patterning process is filled with the second acoustic impedance material. The filling method for the second acoustic impedance material is selected according to the material, such as the doctor blade method, evaporation method, or sputtering method.

As shown in FIG. 10(c), the second acoustic impedance material is ground until the first acoustic impedance film is exposed. The grinding process is selected according to the material, such as chemical or mechanical grinding.

As shown in FIG. 10(d), after the grinding process, an insulating layer 10 is formed. The formation process of the insulating layer 10 is selected according to the material, such as plasma CVD or sputtering. Then, the insulating layer 10 is bonded with the piezoelectric layer 11. Alternatively, the insulating layer 10 can be formed on the piezoelectric layer 11 first, and then bonded with the dielectric layer 12. Finally, by forming the elastic wave element 50 on the piezoelectric layer 11 to meet the required device characteristics and going through the packaging process, the elastic wave device 1 according to the first and second embodiments is obtained.

FIG. 11 is a longitudinal sectional view of a module suitable for the elastic wave device 1 according to the first, second, or third embodiment. The same reference numerals are used for similar or identical structures in the first, second, or third embodiments, and the description is omitted here.

As shown in FIG. 11, the module 100 includes a wiring substrate 130, multiple external connection terminals 131, an integrated circuit component IC, the elastic wave device 1, an inductor 111, and a packaging portion 117.

Multiple external connection terminals 131 are formed on the lower surface of the wiring substrate 130. The external connection terminals 131 are pre-installed on the mainboard of a predetermined mobile communication terminal.

Specifically, the integrated circuit component IC is installed inside the wiring substrate 130. The integrated circuit component IC includes a switching circuit and a low-noise amplifier.

The elastic wave device 1 is mounted on the main surface of the wiring substrate 130.

The inductor 111 is mounted on the main surface of the wiring substrate 130. The inductor 111 is used for impedance matching. For example, the inductor 111 is an Integrated Passive Device (IPD).

The packaging portion 117 is used to encapsulate multiple electronic components, including the elastic wave device 1.

As described above, the module 100 includes the elastic wave device 1. Therefore, a module with good temperature characteristics and significantly reduced spurious response can be provided.

The expressions and terms used in this invention are for illustrative purposes only and should not be construed as limiting. The terms “comprising,” “having,” “including,” and their variations used herein imply the inclusion of the items listed, their equivalents, and additional items.

The term “embodiment” as used in this application refers to the specific features, structures, or characteristics described in connection with the embodiment that may be included in at least one embodiment of the present application. The phrase appears in various places throughout the specification and does not necessarily refer to the same embodiment, nor does it imply that different embodiments are mutually exclusive or independent. It is clear or implicitly understood by those skilled in the art that the embodiments described in this application can be combined with other embodiments where there is no conflict.

The above-described embodiments are merely examples of several implementations of the present application, and their descriptions are relatively specific and detailed, but they should not be construed as limiting the scope of patent protection. It should be noted that, for those skilled in the art, several modifications, corrections, and improvements can be made without departing from the spirit of this application, and these are all within the scope of protection of this application. Therefore, the scope of protection of this application should be based on the attached claims.

What is claimed is:

1. An elastic wave device, comprising:
a supporting substrate;
a dielectric layer formed on the supporting substrate;
an insulating layer formed on the dielectric layer;
a piezoelectric layer formed on the insulating layer;
a resonator, including an IDT electrode, formed on the piezoelectric layer;
wherein the dielectric layer includes a first strip-shaped acoustic impedance region with a long side direction and a short side direction; and a second strip-shaped acoustic impedance region arranged alternately with the first acoustic impedance region and having a different acoustic impedance from that of the first acoustic impedance region; wherein, when the wavelength of the elastic wave determined by the electrode spacing of the IDT electrode is λ, the total thickness of the insulating layer and the piezoelectric layer is 1.0λ or less.

2. The elastic wave device according to claim 1, wherein the wavelength of the elastic wave determined by the electrode spacing of the IDT electrode is λ, the total thickness of the dielectric layer, the insulating layer, and the piezoelectric layer is 1.0λ or less.

3. The elastic wave device according to claim 1, wherein the thickness of the insulating layer is greater than the thickness of the piezoelectric layer.

4. The elastic wave device according to claim 1, wherein the insulating layer is made of a material including silicon dioxide or silicon nitride.

5. The elastic wave device according to claim 1, wherein the insulating layer is made of silicon nitride, and the wavelength of the elastic wave determined by the electrode spacing of the IDT electrode is λ, the total thickness of the insulating layer and the piezoelectric layer is 0.7λ or less.

6. The elastic wave device according to claim 1, wherein the insulating layer is made of silicon dioxide, and the wavelength of the elastic wave determined by the electrode spacing of the IDT electrode is λ, the thickness of the insulating layer is 0.1λ to 0.9λ.

7. The elastic wave device according to claim 6, wherein the velocity of the bulk wave propagating in the insulating layer is lower than the velocity of the bulk wave propagating in the piezoelectric layer.

8. The elastic wave device according to claim 1, wherein the elastic wave device further includes a semiconductor layer formed between the insulating layer and the piezoelectric layer.

9. The elastic wave device according to claim 1, wherein the long side directions of the first acoustic impedance region and the second acoustic impedance region are the same as the long side direction of the electrode fingers of the IDT electrode.

10. The elastic wave device according to claim 1, wherein the first acoustic impedance region and the second acoustic impedance region are arranged at a spacing different from the electrode spacing of the IDT electrode.

11. The elastic wave device according to claim 1, wherein the wavelength of the elastic wave determined by the electrode spacing of the IDT electrode is λ, the thickness of the piezoelectric layer is 0.1λ to 0.3λ.

12. The elastic wave device according to claim 1, wherein the wavelength of the elastic wave determined by the electrode spacing of the IDT electrode is λ, the thickness of the dielectric layer is 0.05λ to 0.45λ.

13. The elastic wave device according to claim 1, wherein the first acoustic impedance region is made of silicon dioxide.

14. The elastic wave device according to claim 1, wherein the second acoustic impedance region is made of alumina, aluminum nitride, silicon nitride, silicon oxynitride, silicon, or silicon carbide.

15. The elastic wave device according to claim 1, wherein the supporting substrate is made of sapphire, silicon, alumina, spinel, crystal, or glass.

16. The elastic wave device according to claim 1, wherein the piezoelectric layer is made of lithium tantalate, lithium niobate, quartz, or piezoelectric ceramic.

17. The elastic wave device according to claim 1, wherein the supporting substrate is a flat rectangular parallelepiped.

18. The elastic wave device according to claim 1, wherein the thickness of the supporting substrate is 50 μm to 200 μm.

19. The elastic wave device according to claim 1, wherein the thickness of the IDT electrode is 150 nm to 450 nm.

20. A module, comprising the elastic wave device according to claim 1.
